(19) United States
(12) Patent Application Publication
(10) Pub. No.: US 2019/0173480 A1
(43) Pub. Date: Jun. 6, 2019

(54) ELECTRONIC CIRCUIT ADJUSTING SKEW BETWEEN PLURALITY OF CLOCKS BASED ON DERIVATIVE OF INPUT SIGNAL

(71) Applicant: KOREA ADVANCED INSTITUTE OF SCIENCE AND TECHNOLOGY, Daejeon (KR)

(72) Inventors: Seung-Tak RYU, Daejeon (KR); Yiju ROH, Daejeon (KR)

(73) Assignee: KOREA ADVANCED INSTITUTE OF SCIENCE AND TECHNOLOGY, Daejeon (KR)

(21) Appl. No.: 16/194,878

(22) Filed: Nov. 19, 2018

(30) Foreign Application Priority Data
Dec. 5, 2017 (KR) 10-2017-0166217

(51) Int. Cl. H03M 1/10; H03K 5/135; H03K 5/1534; H03M 1/08

(52) U.S. Cl. CPC H03M 1/1023; H03K 5/135; H03K 2005/00019; H03M 1/0836; H03K 5/1534

(57) ABSTRACT

An electronic circuit includes a reference ADC and a plurality of sub-ADCs. The reference ADC converts an input signal to reference data in response to a reference clock. The plurality of sub-ADCs may respectively convert the input signal to a plurality of output data, in response respectively to the plurality of conversion clocks providing different timings. Based on a difference between the reference data and each of the plurality of output data and output data corresponding to the difference among the plurality of output data, a timing of a conversion clock associated with the output data corresponding to the difference among the plurality of conversion clocks is adjusted.

### CROSS-REFERENCE TO RELATED APPLICATION

This U.S. non-provisional patent application claims priority under 35 U.S.C. § 119 to Korean Patent Application No. 10-2017-0166217, filed on Dec. 5, 2017, in Korean Intellectual Patent Office, the disclosure of which is incorporated herein by reference in its entirety.

### FIELD

The present disclosure relates to an electronic circuit, and more particularly, relates to configurations and operations for handling a clock that is associated with an operation of the electronic circuit.

### DESCRIPTION OF RELATED ART

Recently, various types of electronic devices are widely being used. An electronic device provides its own function(s) depending on operations of various electronic circuits included in the electronic device. The electronic device may operate alone, or may operate while communicating with another electronic device. The electronic device may include a communication circuit (e.g., a transmission circuit, a reception circuit, and/or the like) for communicating with another electronic device.

Communication between electronic devices may be performed as transmitting and receiving analog signals. On the other hand, most of the electronic devices may operate based on digital data. Accordingly, most of the electronic devices may include an analog-to-digital converter (ADC) to convert the analog signals to the digital data.

Including the communication circuit and the ADC, various electronic circuits may operate in response to a clock. If these electronic circuits do not receive a suitable clock, errors may occur in operations of the electronic circuits or the electronic circuits may operate improperly. This may cause an error in an operation of an electronic device including the electronic circuits. Therefore, it is important to accurately control the clock.

Meanwhile, a circuit design of time-interleaved manner employing a plurality of clocks is being researched to increase communication speed and to process a large amount of data quickly. The plurality of time-interleaved clocks may allow a plurality of electronic circuits to operate in parallel, so that they allow higher performance than a circuit design employing a single clock. However, when timing mismatch occurs in the plurality of clocks, an error may occur in the operations of the electronic circuits or performance of the electronic device may not satisfy the requirements.

### SUMMARY

The present disclosure may provide configurations and operations of an electronic circuit for accurately controlling a plurality of time-interleaved clocks. In some example embodiments, the electronic circuit may adjust (e.g., calibrate) skew between the plurality of clocks, to resolve a timing error between the plurality of clocks.

In some example embodiments, an electronic circuit may include a reference ADC and a plurality of sub-ADCs. The reference ADC may convert an input signal to reference data in response to a reference clock. The plurality of sub-ADCs may convert the input signal to a plurality of output data respectively, in response respectively to a plurality of conversion clocks providing different timings. Based on a difference between the reference data and each of the plurality of output data and output data corresponding to the difference among the plurality of output data, a timing of a conversion clock associated with the output data corresponding to the difference among the plurality of conversion clocks may be adjusted.

In some example embodiments, the electronic circuit may further include a plurality of delay circuits, a subtractor, and an edge detector. The plurality of delay circuits may delay a main clock by different delay times, to respectively output the plurality of conversion clocks which provides different timings. The subtractor may calculate the difference between the reference data and each of the plurality of output data. The edge detector may generate delay calibration values, based on a change in a value of the difference and a value of the output data corresponding to the difference among the plurality of output data. In order to adjust the timing of the conversion clock associated with a sub-ADC which outputs the output data corresponding to the difference among the plurality of sub-ADCs, a delay time of a delay circuit which outputs the conversion clock associated with the sub-ADC outputting the output data corresponding to the difference among the plurality of delay circuits may be adjusted based on the delay calibration values.

For example, when the delay time of the delay circuit increases based on the delay calibration values, a timing of the conversion clock output from the delay circuit may be delayed. For example, when the delay time of the delay circuit decreases based on the delay calibration values, the timing of the conversion clock output from the delay circuit may be advanced. As timings of the plurality of conversion clocks are adjusted, intervals between the timings of the plurality of conversion clocks may be uniform.

According to example embodiments of the present disclosure, a timing error of a plurality of time-interleaved clocks may be resolved. Thus, in a circuit design employing the plurality of clocks, the plurality of clocks may be controlled accurately. As a result, stability and reliability of an operation of an electronic circuit and an electronic device may be improved, and performance of the electronic device may satisfy requirements.

Further, example embodiments of the present disclosure may be provided in real-time (e.g., as a background operation) during an operation of the electronic circuit. Accordingly, timings and skew for a plurality of clocks may be controlled even while the electronic device is operating.

### BRIEF DESCRIPTION OF THE DRAWINGS

The above and other objects and features of the present disclosure will become apparent from the following descriptions with reference to the accompanying figures.

FIG. 1 is a block diagram of an electronic system including example connection between an electronic device employing an ADC circuit according to some example embodiments and another electronic device.

FIG. 2 is a block diagram illustrating an example configuration of an ADC circuit of FIG. 1.

FIG. 3 is a timing diagram illustrating example conversion clocks handled in an ADC circuit of FIG. 2.

FIG. 4 is a timing diagram illustrating timings associated with example conversion clocks of FIG. 3.

FIG. 5 is a timing diagram illustrating example conversion clocks handled in an ADC circuit of FIG. 2.

FIG. 6 is a timing diagram illustrating timings associated with example conversion clocks of FIG. 5.

FIGS. 7 and 8 are timing diagrams for describing an example method of adjusting skew between conversion clocks of FIG. 5.

FIG. 9 is a table for describing an example method of adjusting skew between conversion clocks with regard to timing diagrams of FIGS. 7 and 8.

FIG. 10 is a conceptual diagram for describing a concept of an example method described with reference to FIGS. 7 to 9.

FIG. 11 is a block diagram illustrating an example configuration of an ADC circuit of FIG. 1.

FIG. 12 is a block diagram for describing an example operation of an ADC circuit of FIG. 11.

FIG. 13 is a timing diagram for describing an example operation of an ADC circuit of FIG. 11.

FIG. 14 is a block diagram for describing an example operation of an ADC circuit of FIG. 11.

FIG. 15 is a timing diagram for describing an example operation of an ADC circuit of FIG. 11.

FIG. 16 is a timing diagram for describing an example operation of an ADC circuit of FIG. 11.

FIGS. 17 through 20 are graphs illustrating results of example simulations in which skew between conversion clocks is adjusted according to some example embodiments.

FIG. 21 is a block diagram illustrating an example configuration of an electronic system which employs an ADC circuit according to some example embodiments.

### DETAILED DESCRIPTION

The above-mentioned features and the following detailed descriptions illustrate example embodiments to facilitate better understanding of the present disclosure. The present disclosure is not limited to these example embodiments, but may be implemented in other different aspects. The following example embodiments are merely examples for fully disclosing the present disclosure, and are merely illustrative for conveying the present disclosure to those skilled in the art to which the present disclosure belongs. Therefore, if there are several methods to implement the present disclosure, it is to be possible to implement the present disclosure in any of these methods or any equivalent thereof.

In the following descriptions, when a component is referred to as including a specific component(s) or when a process is referred to as including a specific operation(s), other component(s) or other operation(s) may be further included. The terms used in the following descriptions are provided only to illustrate specific example embodiments, and are not intended to limit the present disclosure. Illustrative examples to facilitate better understanding may also include their complementary example embodiments.

The terms used in the following descriptions may have meanings that are readily understood by those skilled in the art. Commonly used terms should be interpreted consistently in the context of the descriptions. Furthermore, the terms used in the following descriptions should not be interpreted as having excessively ideal or formal meanings, unless their meanings are specifically defined. Hereinafter, some example embodiments will be described with reference to the accompanying drawings.

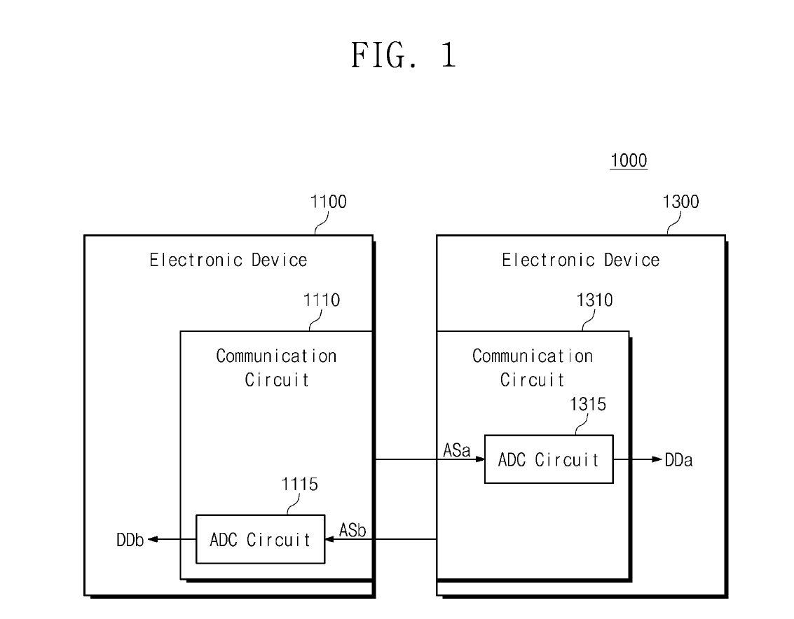

FIG. 1 is a block diagram of an electronic system 1000 including example connection between an electronic device 1300 employing an analog-to-digital converter (ADC) circuit 1315 according to some example embodiments and another electronic device 1100.

The electronic devices 1100 and 1300 may be various kinds of electronic devices. For example, each of the electronic devices 1100 and 1300 may be one of a desktop computer, a laptop computer, a tablet computer, a smart phone, a wearable device, an electric vehicle, a workstation, a server system, and/or the like. The present disclosure is not limited to these examples, and the electronic devices 1100 and 1300 may be implemented with any kind of electronic devices capable of communicating with each other.

The electronic device 1300 may communicate with the electronic device 1100. To this end, the electronic device 1300 may include a communication circuit 1310, and the electronic device 1100 may include a communication circuit 1110. Each of the communication circuits 1110 and 1310 may include various hardware circuits (e.g., an antenna, an amplification circuit, a modulation/demodulation circuit, an encoder/decoder circuit, a clock generator, and/or the like) to facilitate communication between the electronic devices 1100 and 1300.

The communication circuits 1110 and 1310 may operate and be configured in compliance with one or more of a variety of communication protocols. The communication circuits 1110 and 1310 may support at least one of various wired communication protocols such as transfer control protocol/Internet protocol (TCP/IP), universal serial bus (USB), Firewire, and the like and/or at least one of various wireless protocols such as long term evolution (LTE), worldwide interoperability for microwave access (WIMAX), global system for mobile communications (GSM), code division multiple access (CDMA), Bluetooth, wireless fidelity (Wi-Fi), radio frequency identification (RFID), and the like.

The electronic device 1100 may transmit an analog signal ASa to the electronic device 1300 to communicate with the electronic device 1300. The communication circuit 1310 may receive the analog signal ASa from the electronic device 1100. The electronic device 1300 may transmit an analog signal ASb to the electronic device 1100 to communicate with the electronic device 1100. The communication circuit 1110 may receive the analog signal ASb from the electronic device 1300. Communication between the electronic devices 1100 and 1300 may be performed as transmitting and receiving the analog signals ASa and ASb.

Meanwhile, the electronic device 1300 may operate based on digital data DDa obtained from the analog signal ASa, and the electronic device 1100 may operate based on digital data DDb obtained from the analog signal ASb. Thus, the communication circuit 1310 may include an ADC circuit 1315 to convert the analog signal ASa to the digital data DDa, and the communication circuit 1110 may include an ADC circuit 1115 to convert the analog signal ASb to the digital data DDb.

The digital data DDa converted by the ADC circuit 1315 may be provided to another component included in the electronic device 1300, and the electronic device 1300 may provide its own function(s) based on the digital data DDa. The digital data DDb converted by the ADC circuit 1115 may be provided to another component included in the electronic device 1100, and the electronic device 1100 may provide its own function(s) based on the digital data DDb.

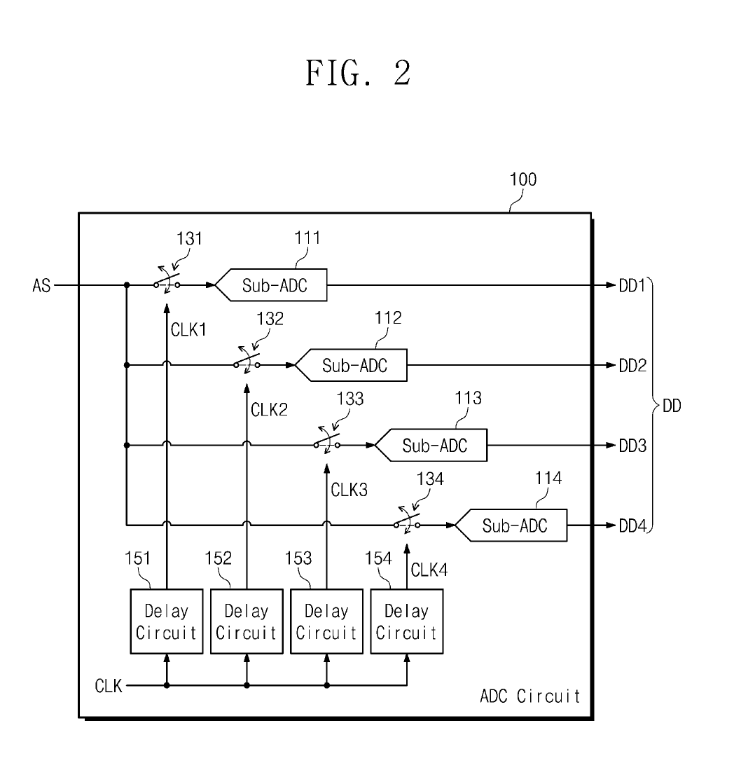

FIG. 2 is a block diagram illustrating an example configuration of the ADC circuit 1115 or 1315 of FIG. 1. In some example embodiments, at least one of the ADC circuits 1115 and/or 1315 of FIG. 1 may include an ADC circuit 100 of FIG. 2.

The ADC circuit 100 may be implemented with an electronic circuit configured to perform operations described above and to be described below. The ADC circuit 100 may include various analog/digital circuits to perform the operations described above and to be described below.

The ADC circuit 100 may include a plurality of sub-ADCs. For example, the ADC circuit 100 may include four sub-ADCs 111, 112, 113, and 114. The four sub-ADCs 111, 112, 113, and 114 are provided to facilitate better understanding, and are not intended to limit the present disclosure. The number of sub-ADCs included in the ADC circuit 100 may be changed or modified differently depending on various factors such as the implementation, a purpose, performance, a use, and/or the like, of the ADC circuit 100. Hereinafter, descriptions regarding the ADC circuit 100 including the four sub-ADCs 111, 112, 113, and 114 will be provided as an example.

The ADC circuit 100 may receive an input signal (e.g., an analog signal AS). Each of the sub-ADCs 111, 112, 113, and 114 may convert the input signal to output data. For example, the sub-ADCs 111, 112, 113, and 114 may convert the input signal to a plurality of output data DD1, DD2, DD3, and DD4 respectively. The output data DD1, DD2, DD3 and DD4 may be handled as digital data DD in an electronic device including the ADC circuit 100.

The sub-ADCs 111, 112, 113, and 114 may be implemented with various types of ADCs to convert the analog signal AS to the output data DD1, DD2, DD3, and DD4. For example, each of the sub-ADCs 111, 112, 113, and 114 may be implemented with one of various types of ADCs such as a successive approximation register (SAR) ADC, a dual slope integration (DSI) ADC, a flash ADC, a delta-sigma modulation (DSM) ADC, and/or the like, but the present disclosure is not limited to these examples. The sub-ADCs 111, 112, 113, and 114 may be implemented with the same type of ADC or with different types of ADCs.

The ADC circuit 100 may include a plurality of switches respectively corresponding to a plurality of sub-ADCs. For example, the ADC circuit 100 may include switches 131, 132, 133 and 134 corresponding to the four sub-ADCs 111, 112, 113, and 114 respectively. The switches 131, 132, 133, and 134 may switch connection to the sub-ADCs 111, 112, 113, and 114 such that the input signal (e.g., the analog signal AS) is provided or not provided to the sub-ADCs 111, 112, 113, and 114.

When the switches 131, 132, 133, and 134 are connected, the input signal may be provided to the sub-ADCs 111, 112, 113, and 114. On the other hand, when the switches 131, 132, 133, and 134 are disconnected, the input signal may not be provided to the sub-ADCs 111, 112, 113, and 114.

When an input signal is provided to an ADC among the sub-ADCs 111, 112, 113, and 114, the ADC may convert the input signal to the output data and output the converted output data. In such a manner, all the sub-ADCs 111, 112, 113, and 114 may output the output data DD1, DD2, DD3, and DD4.

FIG. 2 illustrates that each of the switches 131, 132, 133, and 134 is a switch element, but the present disclosure is not limited to that illustrated in FIG. 2. Each of the switches 131, 132, 133, and 134 may be implemented with any element capable of switching connection, such as a transistor, a capacitor, a gate circuit, and/or the like.

The ADC circuit 100 may employ a plurality of clocks for the plurality of sub-ADCs. For example, conversion clocks CLK1, CLK2, CLK3, and CLK4 may be employed for the sub-ADCs 111, 112, 113, and 114. The switches 131, 132, 133 and 134 may switch the connection in response to the conversion clocks CLK1, CLK2, CLK3 and CLK4 respectively.

As the switches 131, 132, 133 and 134 operate in response to the conversion clocks CLK1, CLK2, CLK3 and CLK4, the sub-ADCs 111, 112, 113, and 114 may operate in response to the conversion clocks CLK1, CLK2, CLK3, and CLK4 respectively. The sub-ADCs 111, 112, 113 and 114 may convert the input signals to the output data DD1, DD2, DD3 and DD4 in parallel, in response to the conversion clocks CLK1, CLK2, CLK3 and CLK4 independently. Thus, the sub-ADCs 111, 112, 113, and 114 may provide higher performance than a single ADC.

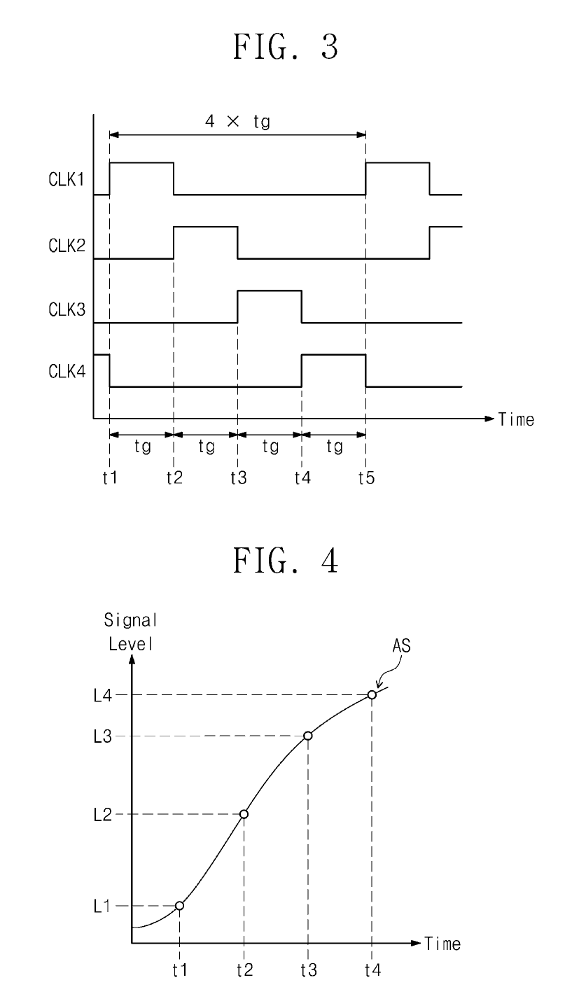

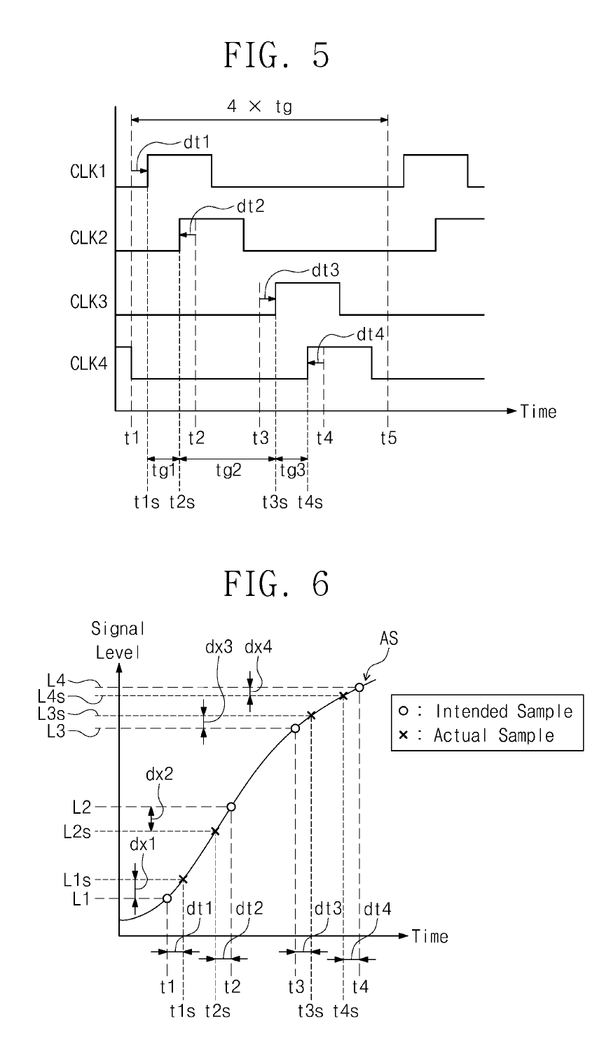

The conversion clocks CLK1, CLK2, CLK3, and CLK4 may provide different timings (e.g., sampling timings of the input signal for analog-to-digital conversion). For example, the conversion clocks CLK1, CLK2, CLK3, and CLK4 may be time-interleaved, which will be described with reference to FIGS. 3 and 4. From this perspective, the ADC circuit 100 may be understood as a time-interleaved ADC or a TI-ADC.

When high processing performance (e.g., analog-to-digital conversion performance) is required in the ADC circuit 100, it may be required to employ a high frequency clock. However, implementing a clock signal at a significantly high frequency may be physically difficult.

Thus, the conversion clocks CLK1, CLK2, CLK3, and CLK4 which are time-interleaved may be employed. Each of the conversion clocks CLK1, CLK2, CLK3, andCLK4 may have a low frequency, and may be relatively easily implemented. Although each of the conversion clocks CLK1, CLK2, CLK3, and CLK4 has a low frequency, the time-interleaved conversion clocks CLK1, CLK2, CLK3, and CLK4 may provide sufficient timing to sample the input signal (e.g., the analog signal AS).

The ADC circuit 100 may include a plurality of delay circuits respectively corresponding to the plurality of clocks. For example, the ADC circuit 100 may include delay circuits 151, 152, 153, and 154 configured to output the conversion clocks CLK1, CLK2, CLK3, and CLK4 respectively.

The delay circuits 151, 152, 153 and 154 may delay a main clock CLK by different delay times, to generate the conversion clocks CLK1, CLK2, CLK3 and CLK4 respectively. The main clock CLK may be provided from a separate clock generator.

The delay times provided by the delay circuits 151, 152, 153, and 154 may be different. The delay circuits 151, 152, 153, and 154 may output the conversion clocks CLK1, CLK2, CLK3, and CLK4 according to the different delay times. Thus, the conversion clocks CLK1, CLK2, CLK3, and CLK4 may provide different timings.

FIG. 3 is a timing diagram illustrating example conversion clocks CLK1, CLK2, CLK3, and CLK4 handled in the ADC circuit 100 of FIG. 2. FIG. 4 is a timing diagram illustrating timings associated with the example conversion clocks CLK1, CLK2, CLK3, and CLK4 of FIG. 3.

Referring to FIG. 3, the conversion clocks CLK1, CLK2, CLK3, and CLK4 may provide different timings (e.g., sampling timings). For example, the conversion clocks CLK1, CLK2, CLK3, and CLK4 may have rising edges at time t1, t2, t3, and t4 respectively.

Therefore, referring to FIG. 4, the sub-ADCs 111, 112, 113 and 114 of FIG. 2 may sample the input signal (e.g., the analog signal AS) at time t1, t2, t3, and t4 respectively (it is assumed that the input signal is sampled at the rising edge). For example, the sub-ADC 111 may sample the analog signal AS at time t1. Therefore, the sub-ADC 111 may output the output data DD1 based on a signal level L1 of the analog signal AS. In this example, it may be understood that the conversion clock CLK1 provides a timing at time t1.

Similarly, the sub-ADCs 112, 113, and 114 may output the output data DD2, DD3, and DD4 based on signal levels L2, L3, and L4 of the analog signal AS sampled at time t2, t3, and t4. Herein, for example, a signal level of the analog signal AS may be a voltage level, but the present disclosure is not limited to this example.

Returning to FIG. 3, the conversion clocks CLK1, CLK2, CLK3, and CLK4 may be time-interleaved. For example, skew of tg may be provided between the conversion clocks CLK1, CLK2, CLK3, and CLK4. Therefore, time intervals of tg may be observed between time t1, t2, t3, t4, and t5 where timings are provided by the conversion clocks CLK1, CLK2, CLK3, and CLK4. As the conversion clocks CLK1, CLK2, CLK3, and CLK4 are time-interleaved, the input signal may be sampled successively at each of the different timings.

A period of each of the conversion clocks CLK1, CLK2, CLK3, and CLK4 may be four times tg. However, as the conversion clocks CLK1, CLK2, CLK3, and CLK4 are time-interleaved, the sampling timings may be provided for each time interval of tg. Implementing the conversion clocks CLK2, CLK3, and CLK4 having the same frequency as that of the conversion clock CLK1 may be physically easier than implementing a clock signal with a higher frequency that is four times that of the conversion clock CLK1.

The sub-ADCs 111, 112, 113, and 114 may operate in parallel in response to the conversion clocks CLK1, CLK2, CLK3, and CLK4 respectively. Therefore, the sub-ADCs 111, 112, 113, and 114 may provide higher performance than a single ADC which operates in response to a single clock having the same frequency as that of the conversion clock CLK1.

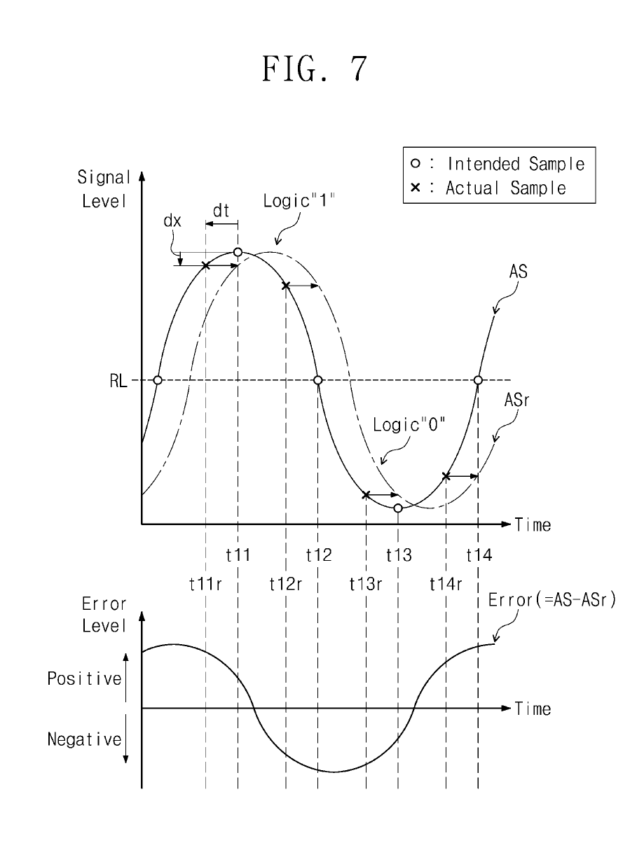

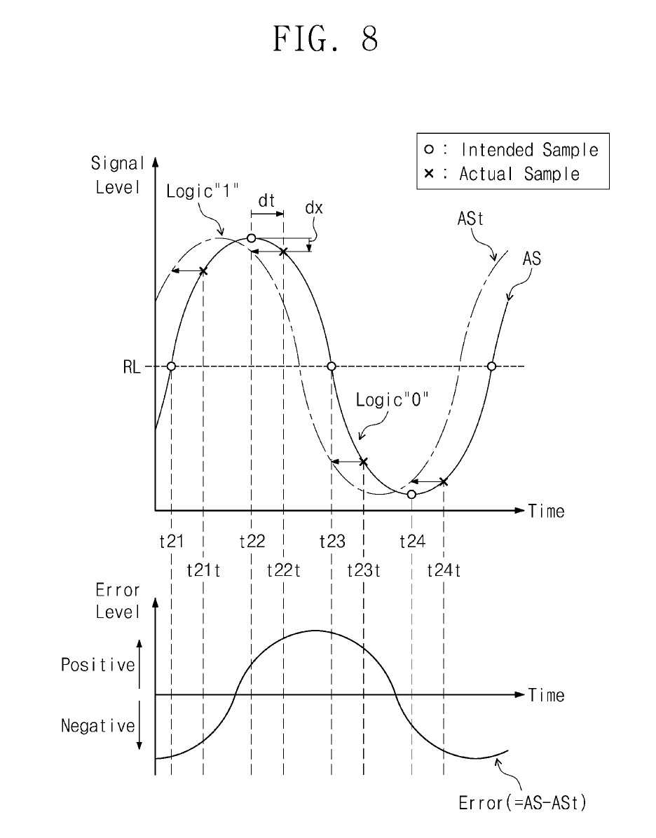

To generate the output data DD1, DD2, DD3, and DD4 accurately and reliably from the input signal (e.g., the analog signal AS), it may be required to maintain the skew of tg between the conversion clocks CLK1, CLK2, CLK3, and CLK4 to be uniform. However, various factors, such as a circuit design issue (e.g., an element characteristic, a difference in physical lengths of clock lines, and/or the like), process-voltage-temperature (PVT) variation, and/or the like, may affect the skew between the conversion clocks CLK1, CLK2, CLK3, and CLK4 and the timings of the conversion clocks CLK1, CLK2, CLK3, and CLK4. This will be described with reference to FIGS. 5 and 6.

FIG. 5 is a timing diagram illustrating example conversion clocks CLK1, CLK2, CLK3, and CLK4 handled in the ADC circuit 100 of FIG. 2. FIG. 6 is a timing diagram illustrating timings associated with the example conversion clocks CLK1, CLK2, CLK3, and CLK4 of FIG. 5.

As described above, various factors may affect the skew between the conversion clocks CLK1, CLK2, CLK3, and CLK4 and the timings of the conversion clocks CLK1, CLK2, CLK3, and CLK4. When the skew between the conversion clocks CLK1, CLK2, CLK3, and CLK4 becomes non-uniform as the conversion clocks CLK1, CLK2, CLK3, and CLK4 are not transmitted as intended, unintended distortion of a frequency component may occur.

Referring to FIG. 5, for example, the timing of the conversion clock CLK1 may become late by a time length dt1, and the timing of the conversion clock CLK2 may become early by a time length dt2. For example, the timing of the conversion clock CLK3 may become late by a time length dt3, and the timing of the conversion clock CLK4 may become early by a time length dt4.

In this case, the timings of the conversion clocks CLK1, CLK2, CLK3, and CLK4 may be provided at time t1s, t2s, t3s, and t4s respectively, rather than the intended time t1, t2, t3, and t4. In addition, the skew between the conversion clocks CLK1, CLK2, CLK3, and CLK4 may become non-uniform with skew of tg1, tg2, and tg3.

Referring to FIG. 6, the sub-ADCs 111, 112, 113 and 114 of FIG. 2 may sample the input signal (e.g., the analog signal AS) at time t1s, t2s, t3s, and t4s respectively. Therefore, timing mismatch of dt1, dt2, dt3, and dt4 may occur between the intended time t1, t2, t3, and t4 and the actual time t1s, t2s, t3s, and t4s. In some cases, setup/hold times of the conversion clocks CLK1, CLK2, CLK3, and CLK4 may not be suitable to sample the analog signal AS.

Due to this, the sub-ADCs 111, 112, 113, and 114 may output the output data DD1, DD2, DD3, and DD4 based on signal levels L1s, L2s, L3s, and L4s of the analog signal AS, instead of the intended signal levels L1, L2, L3, and L4 of the analog signal AS. Errors dx1, dx2, dx3, and dx4 may occur between the intended signal levels L1, L2, L3, and L4 and the actually sampled signal levels L1s, L2s, L3s, and L4s.

Due to the errors, the output data DD1, DD2, DD3, and DD4 may have unintended values. In some cases, the timing error may cause an unintended or unpredictable operation. As an operation speed gets faster, the error becomes worse.

Example embodiments of the present disclosure may detect the timing error between conversion clocks CLK1, CLK2, CLK3, and CLK4 and adjust (e.g., calibrate) the skew between the conversion clocks CLK1, CLK2, CLK3, and CLK4. Thus, the conversion clocks CLK1, CLK2, CLK3, and CLK4 may be accurately controlled. As a result, the ADC circuit 100 and the electronic device including the ADC circuit 100 may operate stably and reliably, and may satisfy requirements such as effective number of bits (ENOB), an error rate, a dynamic range, and/or the like.

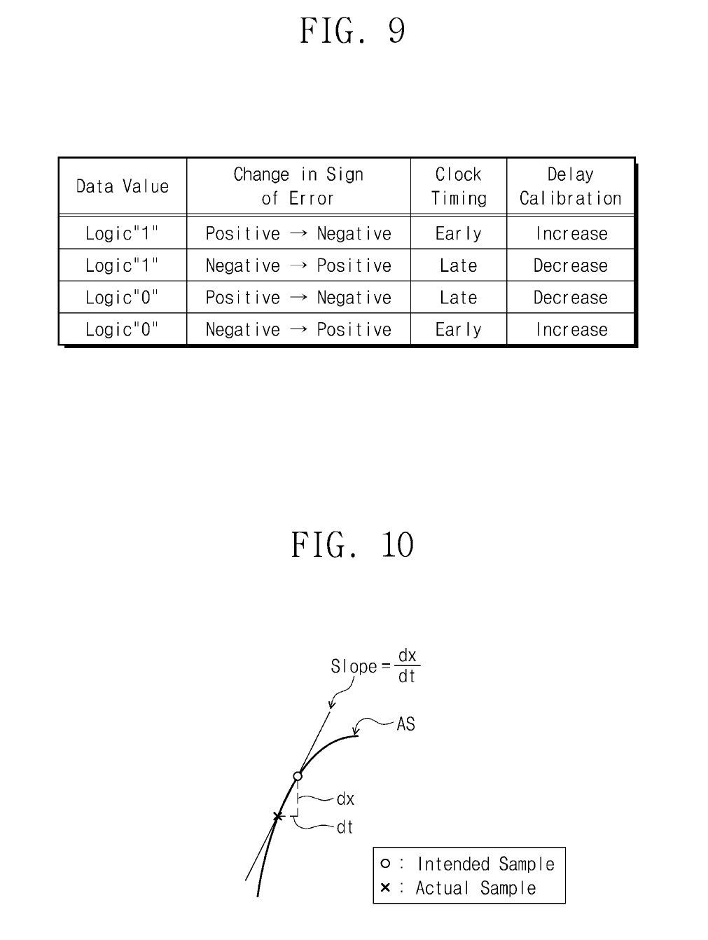

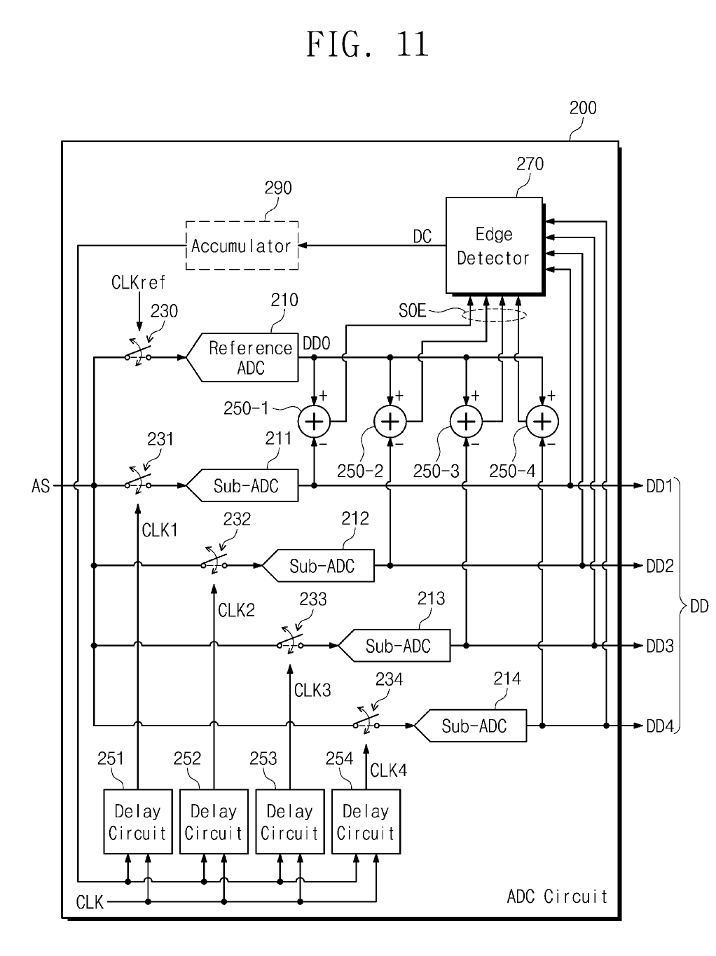

FIGS. 7 and 8 are timing diagrams for describing an example method of adjusting the skew between the conversion clocks CLK1, CLK2, CLK3, and CLK4 of FIG. 5. FIG. 9 is a table for describing an example method of adjusting the skew between the conversion clocks CLK1, CLK2, CLK3, and CLK4 with regard to the timing diagrams of FIGS. 7 and 8.

Referring to FIGS. 7 and 8, a signal level of the analog signal AS may vary over time. For example, the signal level of the analog signal AS may vary depending on a data value.

For example, when the analog signal AS is intended to indicate a first logic value (e.g., logic “1”), the signal level of the analog signal AS may be higher than a reference level RL. On the other hand, when the analog signal AS is intended to indicate a second logic value (e.g., logic “0”), the signal level of the analog signal AS may be lower than the reference level RL.

The analog signal AS may be sampled at each of the timings of the conversion clocks CLK1, CLK2, CLK3 and CLK4, and thus the output data DD1, DD2, DD3, and DD4 may be generated. Each of the output data DD1, DD2, DD3, and DD4 may have a logic value corresponding to the signal level of the sampled input signal. That is, the signal level of the input signal may be associated with the value of the output data.

For example, when the signal level of the sampled input signal is higher than the reference level RL, the output data may be generated to have a first logic value. On the other hand, when the signal level of the sampled input signal is lower than the reference level RL, the output data may be generated to have a second logic value.

The analog signal AS may be sampled at each of the timings of the conversion clocks CLK1, CLK2, CLK3, and CLK4. For example, with regard to the example of FIG. 7, the analog signal AS may be intended to be sampled at time t11, t12, t13, and t14. However, as described above, in some cases, various factors may affect the skew between the conversion clocks CLK1, CLK2, CLK3, and CLK4 and the timings of the conversion clocks CLK1, CLK2, CLK3, and CLK4. In this case, the analog signal AS may be sampled at unintended time.

For example, with regard to the example of FIG. 7, timings of a conversion clock may become earlier than intended ones. For example, the timings of the conversion clock may become early by a time length of dt, and thus the analog signal AS may be sampled at time t11r, t12r, t13r, and t14r rather than time t11, t12, t13, and t14.

In this case, an error may occur with regard to the signal level of the analog signal AS to be sampled. For example, when the analog signal AS is sampled at time t11r rather than time t11, a signal level of the analog signal AS at time t11r may be sampled instead of a signal level of the analog signal AS at time t11 being sampled. Therefore, an error dx may occur.

Taking into account errors associated with time t 11r, t12r, t13r, and t14r, the analog signal AS may appear to be delayed than being intended. For example, it may be observed that the analog signal AS sampled at time t11r, t12r, t13r, and t14r is delayed like an analog signal ASr. It may be understood that the analog signal ASr lags behind the analog signal AS.

Herein, an error may be observed between the signal level of the analog signal AS and the signal level of the analog signal ASr. This error may have an error level corresponding to the difference between the signal level of the analog signal AS and the signal level of the analog signal ASr. The error level may have a positive value or a negative value as a time passes.

With regard to the example of FIG. 7, for example, when the analog signal AS is intended to indicate a first logic value (e.g., logic “1”), the error level may be changed from the positive value to the negative value (i.e., a sign of the error may be changed from positive to negative). On the other hand, for example, when the analog signal AS is intended to indicate a second logic value (e.g., logic “0”), the error level may be changed from the negative value to the positive value (i.e., the sign of the error may be changed from negative to positive).

The logic value intended by the analog signal AS and a change in the error level may be referenced to determine whether timings of a conversion clock are early or late. For example, the change in the error level illustrated in FIG. 7 may indicate that the timings of the conversion clock are earlier than intended ones. Therefore, the change in the error level illustrated in FIG. 7 may be referenced to make the timings of the conversion clock delayed such that the conversion clock is to have intended timings.

Likewise, with regard to the example of FIG. 8, the analog signal AS may be intended to be sampled at time t21, t22, t23, and t24. However, in some cases, various factors may affect the skew between the conversion clocks CLK1, CLK2, CLK3, and CLK4 and the timings of the conversion clocks CLK1, CLK2, CLK3, and CLK4. In this case, the analog signal AS may be sampled at unintended time.

For example, with regard to the example of FIG. 8, timings of a conversion clock may become later than intended ones. For example, the timings of the conversion clock may become late by a time length of dt, and thus the analog signal AS may be sampled at time t21t, t22t, t23t, and t24t, instead of time t21, t22, t23, and t24.

In this case, an error may occur with regard to the signal level of the analog signal AS to be sampled. For example, when the analog signal AS is sampled at time t22r other than time t22, a signal level of the analog signal AS at time t22r may be sampled instead of a signal level of the analog signal AS at time t22 being sampled. Therefore, an error dx may occur.

Taking into account errors associated with time t21t, t22t, t23t, and t24t, the analog signal AS may appear to be advanced than being intended. For example, it may be observed that the analog signal AS sampled at time t21t, t22t, t23t, and t24t is advanced like an analog signal ASt. It may be understood that the analog signal ASt leads to the analog signal AS.

Herein, an error may be observed between the signal level of the analog signal AS and the signal level of the analog signal ASt. This error may have an error level corresponding to the difference between the signal level of the analog signal AS and the signal level of the analog signal ASt.

With regard to the example of FIG. 8, for example, when the analog signal AS is intended to indicate a first logic value (e.g., logic “1”), the error level may be changed from a negative value to a positive value. On the other hand, when the analog signal AS is intended to indicate a second logic value (e.g., logic “0”), the error level may be changed from the positive value to the negative value.

For example, a change in the error level illustrated in FIG. 8 may indicate that the timings of the conversion clock are later than intended ones. Therefore, the change in the error level illustrated in FIG. 8 may be reference to make the timings of the conversion clock advanced such that the conversion clock is to have intended timings.

FIG. 9 illustrates an example method for controlling a conversion clock with regard to the examples of FIGS. 7 and 8. For example, in some cases, the analog signal AS may be intended to indicate a value of logic “1”. When the sign of the error changes from positive to negative while the analog signal AS has a signal level corresponding to logic “1”, this may indicate that timings of a conversion clock is earlier than intended ones (refer to FIG. 7). Thus, example embodiments of the present disclosure may increase a delay of the conversion clock to make the timings of the conversion clock delayed.

On the other hand, when the sign of the error changes from negative to positive while the analog signal AS has a signal level corresponding to logic “1”, this may indicate that timings of a conversion clock is later than intended ones (refer to FIG. 8). Thus, example embodiments of the present disclosure may decrease a delay of the conversion clock to make the timings of the conversion clock advanced.

Meanwhile, in some cases, the analog signal AS may be intended to indicate a value of logic “0”. When the sign of the error changes from positive to negative while the analog signal AS has a signal level corresponding to logic “0”, this may indicate that timings of a conversion clock is later than intended ones (refer to FIG. 8). Thus, example embodiments of the present disclosure may decrease a delay of the conversion clock to make the timings of the conversion clock advanced.

On the other hand, when the sign of the error changes from negative to positive while the analog signal AS has a signal level corresponding to logic “0”, this may indicate that timings of a conversion clock is earlier than intended ones (refer to FIG. 7). Thus, example embodiments of the present disclosure may increase a delay of the conversion clock to make the timings of the conversion clock delayed.

In such a manner, the logic value intended by the analog signal AS and the change in the sign of the error may be referenced to determine whether timings of a conversion clock are early or late. Further, results of the determination may be referenced to adjust a delay and timings of a conversion clock.

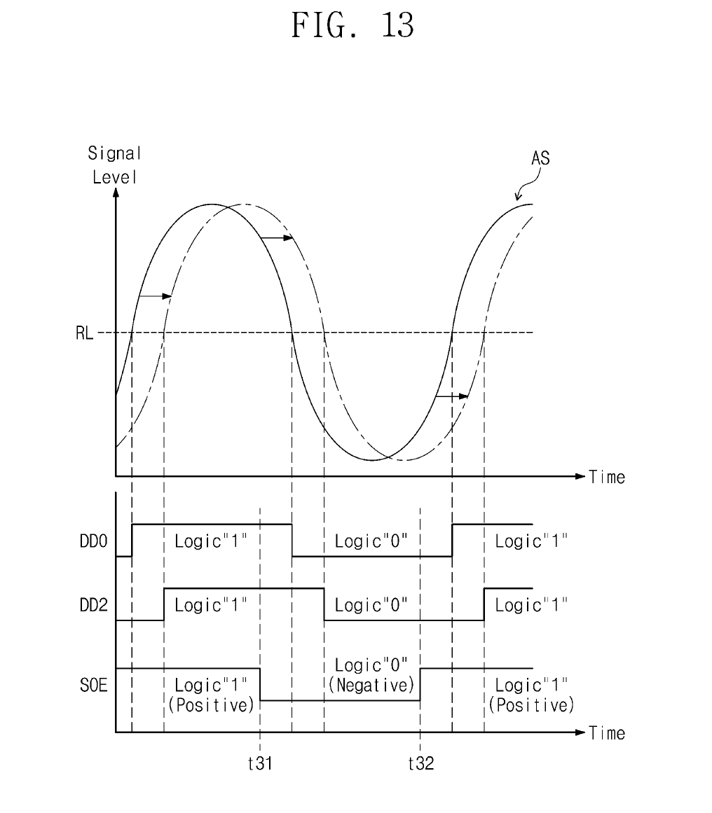

When the delay and the timings of the conversion clocks CLK1, CLK2, CLK3, and CLK4 are adjusted, the timing error of the conversion clocks CLK1, CLK2, CLK3, and CLK4 may be resolved. Example circuit designs for implementing example embodiments of the present disclosure will be described with reference to FIGS. 11 to 16.

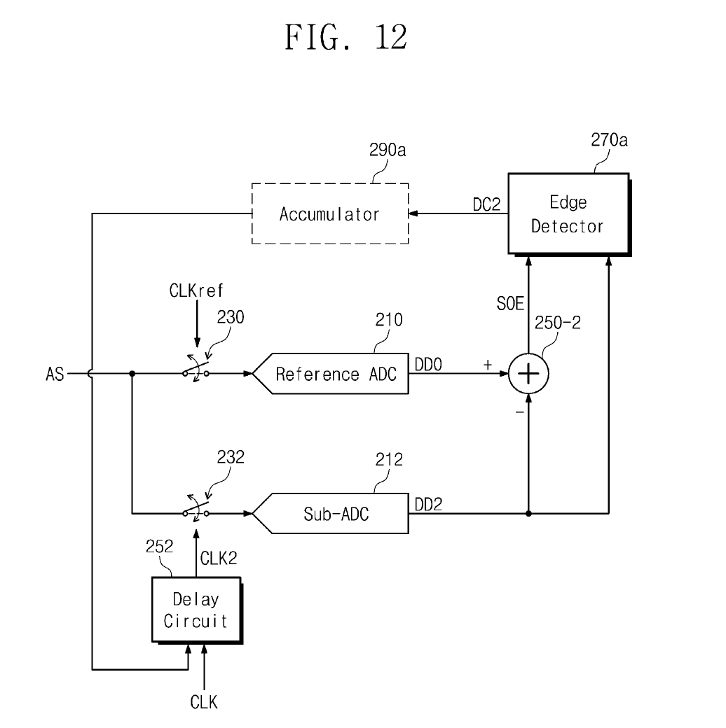

FIG. 10 is a conceptual diagram for describing a concept of the example method described with reference to FIGS. 7 to 9.

When various factors affects the skew between the conversion clocks CLK1, CLK2, CLK3, and CLK4 and the timings of the conversion clocks CLK1, CLK2, CLK3, and CLK4, the analog signal AS may be sampled at unintended time. For example, an error dt may occur between a timing associated with an intended sample and a timing associated with a sample actually being sampled, and an error dx may occur between a signal level associated with the intended sample and a signal level associated with the sample actually being sampled. As described above, example embodiments of the present disclosure may adjust the timings of the conversion clocks CLK1, CLK2, CLK3, and CLK4 based on a change in a sign of the error dx.

Meanwhile, with regard to the intended sample and the sample actually being sampled, a slope (e.g., dx/dt) on the analog signal AS may be provided. Herein, when intervals between the timings of the conversion clocks CLK1, CLK2, CLK3 and CLK4 becomes narrower (for example, when respective frequencies of the conversion clocks CLK1, CLK2, CLK3 and CLK4 are high), the error dt may become sufficiently small. In this case, it may be understood that the error dx corresponds to a derivative of the analog signal AS.

From this perspective, example embodiments of the present disclosure may be regarded as adjusting the timings of the conversion clocks CLK1, CLK2, CLK3, and CLK4 based on the derivative of the input signal (e.g., the analog signal AS). Thus, conceptually, example embodiments of the present disclosure may be understood as being capable of adjusting the skew between the conversion clocks CLK1, CLK2, CLK3, and CLK4 based on the derivative of the input signal.

FIG. 11 is a block diagram illustrating an example configuration of the ADC circuit 1115 or 1315 of FIG. 1. In some example embodiments, at least one of the ADC circuits 1115 and/or 1315 of FIG. 1 may include an ADC circuit 200 of FIG. 11.

The ADC circuit 200 may be implemented with an electronic circuit configured to perform operations to be described below. The ADC circuit 200 may include various analog/digital circuits to perform the operations to be described below. For example, the ADC circuit 200 may include a plurality of sub-ADCs, a plurality of switches, and a plurality of delay circuits. For example, the ADC circuit 200 may include sub-ADCs 211, 212, 213 and 214, switches 231, 232, 233 and 234, and delay circuits 251, 252, 253 and 254.

FIG. 11 illustrates an implementation associated with the four sub-ADCs 211, 212, 213, 214 to facilitate better understanding. However, the present disclosure is not limited to that illustrated in FIG. 11. The number of sub-ADCs included in the ADC circuit 200 may be variously changed or modified.

The sub-ADCs 211, 212, 213 and 214, the switches 231, 232, 233 and 234, and the delay circuits 251, 252, 253 and 254 correspond to the sub-ADCs 111, 112, 113 and 114, the switches 131, 132, 133 and 134, and the delay circuits 151, 152, 153 and 154. For brevity, redundant descriptions associated with the sub-ADCs 211, 212, 213 and 214, the switches 231, 232, 233 and 234, and the delay circuits 251, 252, 253 and 254 will be omitted below.

The ADC circuit 200 may include a reference ADC 210. The reference ADC 210 may convert the input signal (e.g., the analog signal AS) to reference data DD0. The reference ADC 210 may be implemented with one of various types of ADCs to convert the analog signal AS to the reference data DD0. The reference ADC 210 may include an ADC which is the same type as or a different type from the sub-ADCs 211, 212, 213, and 214. The reference ADC 210 may be configured to have the same resolution as each of the sub-ADCs 211, 212, 213, and 214.

The ADC circuit 200 may include a switch 230 corresponding to the reference ADC 210. The switch 230 may switch connection to the reference ADC 210 such that the input signal is provided or not provided to the reference ADC 210. The switch 230 may be implemented with any element capable of switching connection, such as a switch element, a transistor, a capacitor, a gate circuit, and/or the like.

When the switch 230 is connected, the input signal may be provided to the reference ADC 210. On the other hand, when the switch 230 is disconnected, the input signal may not be provided to the reference ADC 210.

The switch 230 may switch the connection in response to a reference clock CLKref. That is, the input signal may be or may not be provided to the reference ADC 210 in response to the reference clock CLKref, and thus the reference ADC 210 may convert the input signal to the reference data DD0 and may output the converted reference data DD0 in response to the reference clock CLKref.

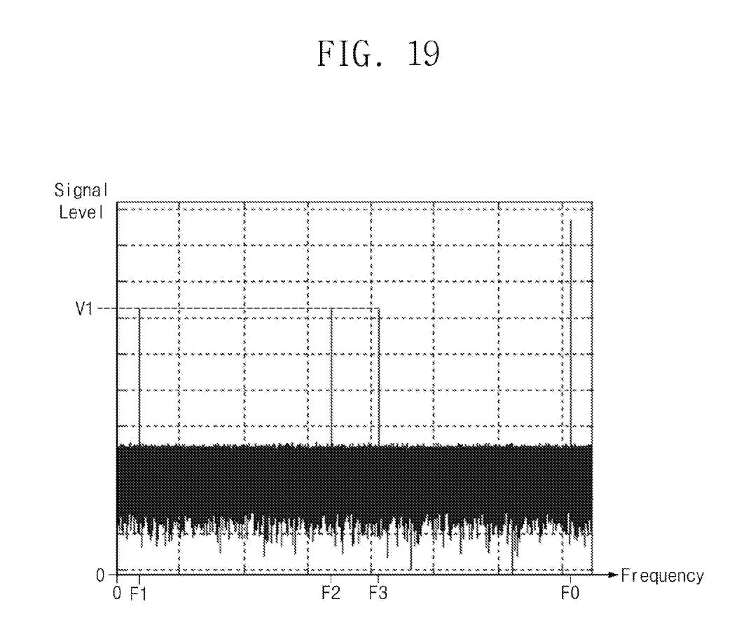

The reference clock CLKref may be converted from the main clock CLK, or may be provided from a separate clock generator. An example relationship between the reference clock CLKref and the conversion clocks CLK1, CLK2, CLK3, and CLK4 will be described with reference to FIG. 16.

The reference clock CLKref may also provide a timing like each of the conversion clocks CLK1, CLK2, CLK3, and CLK4. For example, the reference clock CLKref may provide a reference timing. The reference timing may correspond to an intended timing which facilitates intended sampling described with reference to FIGS. 3 to 9.

The reference clock CLKref may be provided independently of the conversion clocks CLK1, CLK2, CLK3, and CLK4. Accordingly, the reference clock CLKref may be irrespective of time-interleaving, and may not be affected by the timing error between the conversion clocks CLK1, CLK2, CLK3, and CLK4. Taking into account this characteristic, the timing of the reference clock CLKref may be used as a reference for adjusting the timings of the conversion clocks CLK1, CLK2, CLK3, and CLK4.

In the example embodiments of the present disclosure, the timings of the conversion clocks CLK1, CLK2, CLK3, and CLK4 may be adjusted based on the reference clock CLKref. Therefore, the conversion clocks CLK1, CLK2, CLK3, and CLK4 may be aligned based on the reference clock CLKref. As a result, a timing error between the conversion clocks CLK1, CLK2, CLK3, and CLK4 may be resolved.

The ADC circuit 200 may include subtractors 250-1 to 250-4. The subtractors 250-1 to 250-4 may calculate and output differences between the reference data DD0 and the output data DD1, DD2, DD3 and DD4. As described with reference to FIGS. 7 to 9, a difference (i.e., an error) between a signal characteristic associated with the intended sample and a signal characteristic associated with the actually sampled sample may be referenced to determine whether the timings of the conversion clocks CLK1, CLK2, CLK3, and CLK4 are early or late. The subtractors 250-1 to 250-4 may be employed to consider the error.

The reference data DD0 may be generated from an intended sample based on the reference clock CLKref providing the reference timing. On the other hand, each of the output data DD1, DD2, DD3 and DD4 may be generated from actual samples based on time-interleaved conversion clocks CLK1, CLK2, CLK3, and CLK4. Therefore, a difference (i.e., an error) between the reference data DD0 and each of the output data DD1, DD2, DD3, and DD4 may be referenced to determine whether the timings of the conversion clocks CLK1, CLK2, CLK3, and CLK4 are early or late.

The subtractors 250-1 to 250-4 may output a sign of error SOE. The sign of error SOE may indicate whether the difference between the reference data DD0 and the output data DD1, DD2, DD3, and DD4 is positive or negative. The sign of error SOE may be referenced to determine whether the timings of the conversion clocks CLK1, CLK2, CLK3, and CLK4 are early or late. In some example embodiments, when each of the data DD0, DD1, DD2, DD3, and DD4 includes a plurality of bits, each of the subtractors 250-1 to 250-4 may perform a subtraction operation on all the plurality of bits, but the present disclosure is not limited to this example.

The sign of error SOE may have different values depending on whether a value of the reference data DD0 is larger or smaller than a value of each of the output data DD1, DD2, DD3 and DD4. When the value of the reference data DD0 is different from the value of each of the output data DD1, DD2, DD3, and DD4, the sign of error SOE may have a value corresponding to the difference between the reference data DD0 and each of the output data DD1, DD2, DD3 and DD4. In some example embodiments, when the value of the reference data DD0 is identical to the value of each of the output data DD1, DD2, DD3 and DD4, each of the subtractors 250-1 to 250-4 may maintain a previous value of the sign of error SOE.

The ADC circuit 200 may include an edge detector 270. The edge detector 270 may generate delay calibration values DC. The delay calibration values DC may be referenced to adjust (e.g., increase or decrease) delay times of the delay circuits 251, 252, 253, and 254. When the delay times of the delay circuits 251, 252, 253 and 254 are adjusted based on the delay calibration values DC, the timings of the conversion clocks CLK1, CLK2, CLK3, and CLK4 may be adjusted (e.g., delayed or advanced).

The edge detector 270 may generate the delay calibration values DC based on the difference between the reference data DD0 and each of the output data DD1, DD2, DD3, and DD4. Further, the edge detector 270 may generate the delay calibration values DC based on each of the output data DD1, DD2, DD3, and DD4. To this end, the edge detector 270 may receive the sign of error SOE and the output data DD1, DD2, DD3, and DD4.

As described with reference to FIGS. 7 to 9, the logic value of the output data DD1, DD2, DD3 and DD4 and the difference between the reference data DD0 and each of the output data DD1, DD2, DD3 and DD4 may be referenced to determine whether the timings of the conversion clocks CLK1, CLK2, CLK3, and CLK4 are early or late. Therefore, to determine the timings of the conversion clocks CLK1, CLK2, CLK3, and CLK4 and generate suitable delay calibration values DC, the edge detector 270 may use the output data DD1, DD2, DD3, and DD4 and the sign of error SOE.

For example, the edge detector 270 may generate the delay calibration values DC by combining a change in a value of the difference calculated by the subtractors 250-1 to 250-4 (i.e., a change in the sign of error SOE) with the value of the output data DD1, DD2, DD3, and DD4. To this end, for example, the edge detector 270 may include a combinational logic circuit.

For example, the edge detector 270 may detect an edge of the sign of error SOE that occurs while the value of the output data DD1, DD2, DD3, and DD4 are maintained. Thus, the edge detector 270 may detect the change in the sign of error SOE (i.e., the change in the value of the difference calculated by the subtractors 250-1 to 250-4). To this end, for example, the edge detector 270 may include various analog/digital circuits such as a phase detection circuit and/or the like. The edge detector 270 may generate the delay calibration values DC based on result of the detection.

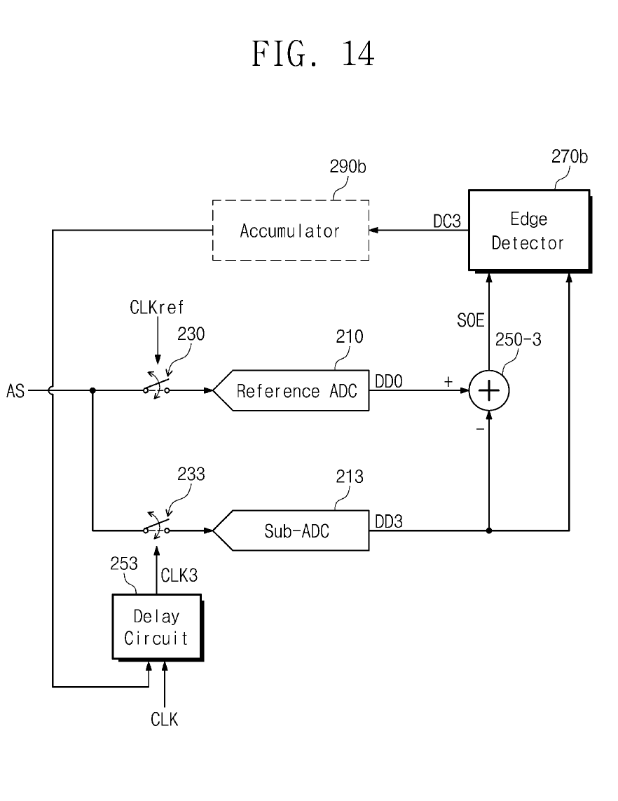

As will be described with reference to FIGS. 12 to 16, the delay times of the delay circuits 251, 252, 253 and 254 may be adjusted independently or separately based on the delay calibration values DC. For example, the delay time of the delay circuit 251 may be adjusted to adjust the timing of the conversion clock CLK1, and the delay time of the delay circuit 254 may be adjusted to adjust the timing of the conversion clock CLK4. The delay time of the delay circuit 251 may be adjusted independently from the delay time of the delay circuit 254.

A delay time of a delay circuit may be adjusted based on output data which is output from a sub-ADC operating in response to a conversion clock output from the delay circuit. A delay calibration value generated based on output data may be referenced to adjust a delay time of a delay circuit which outputs a conversion clock used to operate a sub-ADC generating the output data.

The edge detector 270 may generate the delay calibration values DC based on the difference between the reference data DD0 and output data and the output data corresponding to the difference. The generated delay calibration values DC may be referenced to adjust a delay time of a delay circuit which outputs a conversion clock associated with a sub-ADC outputting the output data. Thus, a timing of the conversion clock associated with the sub-ADC outputting the output data may be adjusted.

For example, the subtractor 250-1 may output the sign of error SOE based on the difference between the reference data DD0 and the output data DD1. The edge detector 270 may receive the sign of error SOE. The edge detector 270 may further receive the output data DD1 corresponding to the sign of error SOE. The edge detector 270 may output the delay calibration values DC based on the sign of error SOE and the output data DD1. The delay calibration values DC may be generated to adjust the timing of the conversion clock CLK1 associated with the sub-ADC 211 outputting the output data DD1. To this end, the delay time of the delay circuit 251 outputting the conversion clock CLK1 may be adjusted based on the delay calibration values DC.

In some example embodiments, the ADC circuit 200 may include an accumulator 290. The accumulator 290 may accumulate the delay calibration values DC output from the edge detector 270. The accumulator 290 may generate a final calibration value based on the accumulated delay calibration values DC. The delay time of each of the delay circuits 251, 252, 253, and 254 may be adjusted (e.g., increased or decreased) based on the final calibration value.

The accumulator 290 may accumulate the delay calibration values DC separately for each of the delay circuits 251, 252, 253, and 254. For example, the accumulator 290 may independently accumulate the delay calibration values DC for the delay circuit 251 and the delay calibration values DC for the delay circuit 254.

For example, the accumulator 290 may accumulate the delay calibration values DC for a reference time duration. Alternatively, for example, the accumulator 290 may accumulate the delay calibration values DC until the reference number of delay calibration values is accumulated.

In some cases, the delay calibration values DC may be generated too frequently or the delay calibration values DC may include a noise. Due to this reason, adjusting a delay time for each timing of the conversion clocks CLK1, CLK2, CLK3, and CLK4 may be inefficient or ineffective. Thus, the accumulator 290 may accumulate the delay calibration values DC depending on intended criteria and may output the final correction value. The final correction value may be referenced to suitably adjust the delay times for the conversion clocks CLK1, CLK2, CLK3, and CLK4 based on the delay calibration values collected sufficiently.

For example, the accumulator 290 may include a logic circuit for summing the delay calibration values DC. For example, the accumulator 290 may include a low-pass filter (LPF) to filter the delay calibration values DC. The configuration of the accumulator 290 may be variously modified or changed to accumulate the delay calibration values DC.

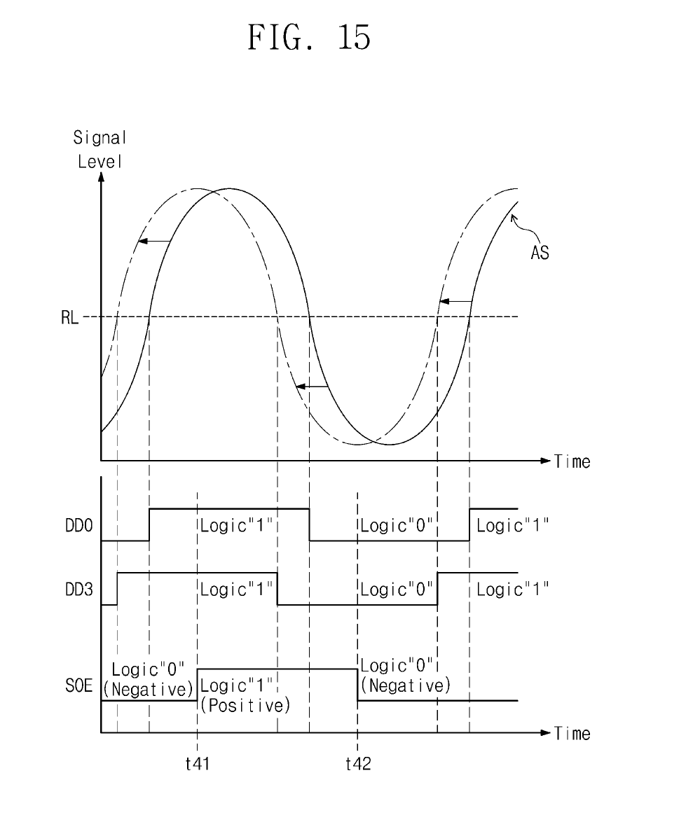

FIG. 12 is a block diagram for describing an example operation of the ADC circuit 200 of FIG. 11. FIG. 13 is a timing diagram for describing an example operation of the ADC circuit 200 of FIG. 11.

FIG. 12 illustrates some components included in the ADC circuit 200. The components of FIG. 12 may be configured to adjust the timings of the conversion clock CLK2 associated with the sub-ADC 212. The sub-ADC 212 may convert the analog signal AS to the output data DD2 in response to the conversion clock CLK2. The reference ADC 210 may convert the analog signal AS to the reference data DD0 in response to the reference clock CLKref. The subtractor 250-2 may output the sign of error SOE based on the difference between the reference data DD0 and the output data DD2.

An edge detector 270a included in the edge detector 270 may generate delay calibration values DC2 that are referenced to adjust the timings of the conversion clock CLK2. To this end, the edge detector 270a may receive a sign of error SOE associated with a value of a difference between the reference data DD0 and the output data DD2. Further, the edge detector 270a may receive the output data DD2.

The edge detector 270a may output the delay calibration values DC2 based on the sign of error SOE and the output data DD2. In some example embodiments, an accumulator 290a included in the accumulator 290 may accumulate the delay calibration values DC2 to generate a final correction value. The delay calibration values DC2 or the final correction value may be referenced to adjust the delay time of the delay circuit 252. As the delay time of the delay circuit 252 is adjusted, the timings of the conversion clock CLK2 may be adjusted.

For example, the timings of the conversion clock CLK2 may be earlier than intended timings (e.g., by the time length dt2), as described with reference to FIGS. 5 and 6. In this example, the delay time of the delay circuit 252 may increase based on the delay calibration values DC2 or the final correction value, and thus the timings of the conversion clock CLK2 may be delayed.

Referring to FIG. 13, each of the reference data DD0 and the output data DD2 may have a value of logic “1” or logic “0” depending on the signal level of the analog signal AS. For example, logic values of the reference data DD0 and the output data DD2 illustrated in FIG. 13 may be logic values of the most significant bits (MSB) of the reference data DD0 and the output data DD2. Meanwhile, when the timings of the conversion clock CLK2 are earlier than the intended timings, the output data DD2 may appear to lag behind the reference data DD0 (refer to FIG. 7).

The subtractor 250-2 may output the sign of error SOE based on the difference between the reference data DD0 and the output data DD2. For example, the subtractor 250-2 may generate the sign of error SOE by performing a subtraction operation on all of a plurality of bits of the reference data DD0 and the output data DD2. For example, when the difference between the reference data DD0 and the output data DD2 has a positive value, the sign of error SOE may have a value of logic “1”. On the other hand, when the difference between the reference data DD0 and the output data DD2 has a negative value, the sign of error SOE may have a value of logic “0”. For example, when the value of the reference data DD0 is identical to the value of the output data DD2, the sign of error SOE may maintain a previous value.

The edge detector 270a may, for example, determine whether the timings of the conversion clock CLK2 are early or late, based on the change in the sign of error SOE and the value of the output data DD2. Further, the edge detector 270a may generate and output the delay calibration values DC2 based on result of the determination.

For example, at time t31, the output data DD2 may correspond to a first logic value (e.g., logic “1”). When the sign of error SOE changes from a first logic value (e.g., logic “1”) to a second logic value (e.g., logic “2”) while the value of the output data DD2 is maintained at the first logic value, the edge detector 270a may determine that the timings of the conversion clock CLK2 are early (refer to FIGS. 7 and 9).

For example, at time t32, the output data DD2 may correspond to a second logic value (e.g., logic “0”). When the sign of error SOE changes from a second logic value (e.g., logic “0”) to a first logic value (e.g., logic “1”) while the value of the output data DD2 is maintained at the second logic value, the edge detector 270a may determine that the timings of the conversion clock CLK2 are early (refer to FIGS. 7 and 9).

In the above examples, the edge detector 270a may generate the delay calibration value DC2 to increase the delay time of the delay circuit 252 outputting the conversion clock CLK2. When the delay time of the delay circuit 252 increases based on the delay calibration values DC2, the timings of the conversion clock CLK2 may be delayed.

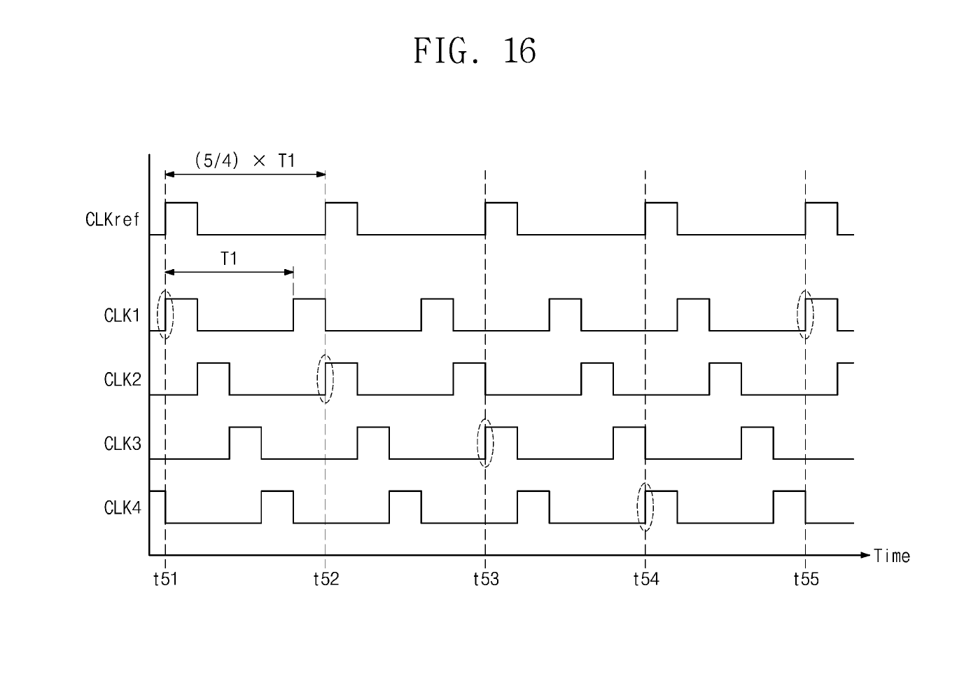

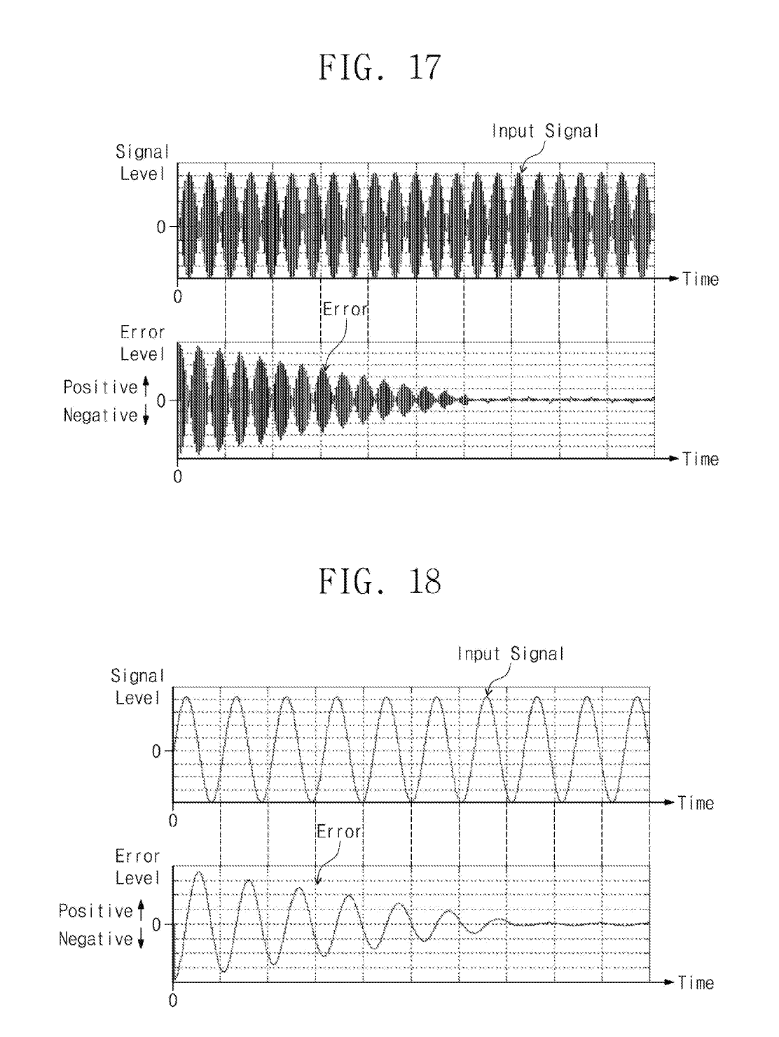

FIG. 14 is a block diagram for describing an example operation of the ADC circuit 200 of FIG. 11. FIG. 15 is a timing diagram for describing an example operation of the ADC circuit 200 of FIG. 11.

FIG. 14 illustrates some components included in the ADC circuit 200. The components of FIG. 14 may be configured to adjust the timings of the conversion clock CLK3 associated with the sub-ADC 213. The sub-ADC 213 may convert the analog signal AS to the output data DD2 in response to the conversion clock CLK3. The reference ADC 210 may convert the analog signal AS to the reference data DD0 in response to the reference clock CLKref. The subtractor 250-3 may output the sign of error SOE based on the difference between the reference data DD0 and the output data DD3.

An edge detector 270b included in the edge detector 270 may generate delay calibration values DC3 that are referenced to adjust the timings of the conversion clock CLK3. To this end, the edge detector 270b may receive a sign of error SOE associated with a value of a difference between the reference data DD0 and the output data DD3. Further, the edge detector 270b may receive the output data DD3.

The edge detector 270b may output the delay calibration values DC3 based on the sign of error SOE and the output data DD3. In some example embodiments, an accumulator 290b included in the accumulator 290 may accumulate the delay calibration values DC3 to generate a final correction value. The delay calibration values DC3 or the final correction value may be referenced to adjust the delay time of the delay circuit 253. As the delay time of the delay circuit 253 is adjusted, the timings of the conversion clock CLK3 may be adjusted.

For example, the timings of the conversion clock CLK3 may be later than intended timings (e.g., by the time length dt3), as described with reference to FIGS. 5 and 6. In this example, the delay time of the delay circuit 253 may decrease based on the delay calibration values DC3 or the final correction value, and thus the timings of the conversion clock CLK3 may be advanced.

Referring to FIG. 15, each of the reference data DD0 and the output data DD3 may have a value of logic “1” or logic “0” depending on the signal level of the analog signal AS. For example, logic values of the reference data DD0 and the output data DD3 illustrated in FIG. 15 may be logic values of the MSBs of the reference data DD0 and the output data DD3. Meanwhile, when the timings of the conversion clock CLK3 are later than the intended timings, the output data DD3 may appear to lead to the reference data DD0 (refer to FIG. 8).

The subtractor 250-3 may output the sign of error SOE based on the difference between the reference data DD0 and the output data DD3. For example, the subtractor 250-3 may generate the sign of error SOE by performing a subtraction operation on all of a plurality of bits of the reference data DD0 and the output data DD3. For example, when the difference between the reference data DD0 and the output data DD3 has a positive value, the sign of error SOE may have a value of logic “1”. On the other hand, when the difference between the reference data DD0 and the output data DD3 has a negative value, the sign of error SOE may have a value of logic “0”. For example, when the value of the reference data DD0 is identical to the value of the output data DD3, the sign of error SOE may maintain a previous value.

The edge detector 270b may, for example, determine whether the timings of the conversion clock CLK3 are early or late, based on the change in the sign of error SOE and the value of the output data DD3. Further, the edge detector 270b may generate and output the delay calibration values DC3 based on result of the determination.

For example, at time t41, the output data DD3 may correspond to a first logic value (e.g., logic “1”). When the sign of error SOE changes from a second logic value (e.g., logic “0”) to a first logic value (e.g., logic “1”) while the value of the output data DD3 is maintained at the first logic value, the edge detector 270b may determine that the timings of the conversion clock CLK3 are late (refer to FIGS. 8 and 9).

For example, at time t42, the output data DD3 may correspond to a second logic value (e.g., logic “0”). When the sign of error SOE changes from a first logic value (e.g., logic “1”) to a second logic value (e.g., logic “0”) while the value of the output data DD3 is maintained at the second logic value, the edge detector 270b may determine that the timings of the conversion clock CLK3 are late (refer to FIGS. 8 and 9).

In the above examples, the edge detector 270b may generate the delay calibration value DC3 to decrease the delay time of the delay circuit 253 outputting the conversion clock CLK3. When the delay time of the delay circuit 253 decreases based on the delay calibration values DC3, the timings of the conversion clock CLK3 may be advanced.

FIG. 16 is a timing diagram for describing an example operation of the ADC circuit 200 of FIG. 11. FIG. 16 illustrates an example relationship between the reference clock CLKref and the conversion clocks CLK1, CLK2, CLK3, and CLK4.

In some example embodiments, a period of the reference clock CLKref may be longer than a period of each of the conversion clocks CLK1, CLK2, CLK3, and CLK4. For example, when four conversion clocks CLK1, CLK2, CLK3, and CLK4 are employed and the period of each of the conversion clocks CLK1, CLK2, CLK3, and CLK4 is T1, the period of the reference clock CLKref may be (5/4) times T1. In this example, a timing of the reference clock CLKref may correspond to a timing of different conversion clock for each period of the reference clock CLKref.

For example, at time t51 at which the first period of the reference clock CLKref starts, the timing of the reference clock CLKref may correspond to the timing of the conversion clock CLK1. Thus, the sub-ADC 211 may operate together with the reference ADC 210, and the reference data DD0 and the output data DD1 may be generated. Further, to adjust the timings of the conversion clock CLK1, the delay time of the delay circuit 251 may be adjusted based on the reference data DD0 and the output data DD1.

Afterwards, at time t52 at which the next period of the reference clock CLKref starts, the timing of the reference clock CLKref may correspond to the timing of the conversion clock CLK2. Thus, the sub-ADC 212 may operate together with the reference ADC 210, and the reference data DD0 and the output data DD2 may be generated. Further, to adjust the timings of the conversion clock CLK2, the delay time of the delay circuit 252 may be adjusted based on the reference data DD0 and the output data DD2.

In such a manner, at the following time t53, t54, and t55, the timings of the reference clock CLKref may correspond to the timings of the conversion clocks CLK3, CLK4, and CLK1 respectively. Thus, a different sub-ADC may operate together with the reference ADC 210 for each period of the reference clock CLKref. As a result, different output data may be generated for each period of the reference clock CLKref.

The subtractors 250-1 to 250-4 may receive the reference data DD0 and one of the output data DD1, DD2, DD3, and DD4. Output data used to calculate a difference by the subtractors 250-1 to 250-4 may be changed for each period of the reference clock CLKref. Therefore, the output data used to calculate the difference may be changed among the output data DD1, DD2, DD3, and DD4 whenever the subtractors 250-1 to 250-4 calculate the difference.

As the timings of the reference clock CLKref consecutively correspond to the timings of all the conversion clocks CLK1, CLK2, CLK3, and CLK4, the subtractors 250-1 to 250-4 may calculate differences between the reference data DD0 and all the output data DD1, DD2, DD3 and DD4. Further, based on the differences calculated by the subtractors 250-1 to 250-4, the edge detector 270 may generate the delay calibration values DC for all the delay circuits 251, 252, 253, and 254.

As the delay times of all the delay circuits 251, 252, 253, and 254 are adjusted based on the delay calibration values DC, the timings of all the conversion clocks CLK1, CLK2, CLK3, and CLK4 may be adjusted. When timings of a conversion clock are earlier than intended timings, the timings of the conversion clock may be delayed. On the other hand, when timings of a conversion clock are later than intended timings, the timings of the conversion clock may be advanced. Accordingly, intervals between different timings of the conversion clocks CLK1, CLK2, CLK3, and CLK4 may become uniform, and a timing error of the conversion clocks CLK1, CLK2, CLK3, and CLK4 may be resolved.

However, the reference clock CLKref and the conversion clocks CLK1, CLK2, CLK3, and CLK4 in FIG. 16 are provided to facilitate better understanding, and are not intended to limit the present disclosure. The reference clock CLKref may be variously changed or modified to adjust the timings of all the conversion clocks CLK1, CLK2, CLK3, and CLK4.

Example embodiments of the present disclosure may be implemented simply. The timings of the conversion clocks CLK1, CLK2, CLK3, and CLK4 may be adjusted based only on data itself and a difference between the data. Further, example embodiments of the present disclosure may be provided in real time (e.g., as a background operation) during an operation of the ADC circuit 200. Even while the ADC circuit 200 is operating, the timings and the skew of the conversion clocks CLK1, CLK2, CLK3, and CLK4 may be controlled.

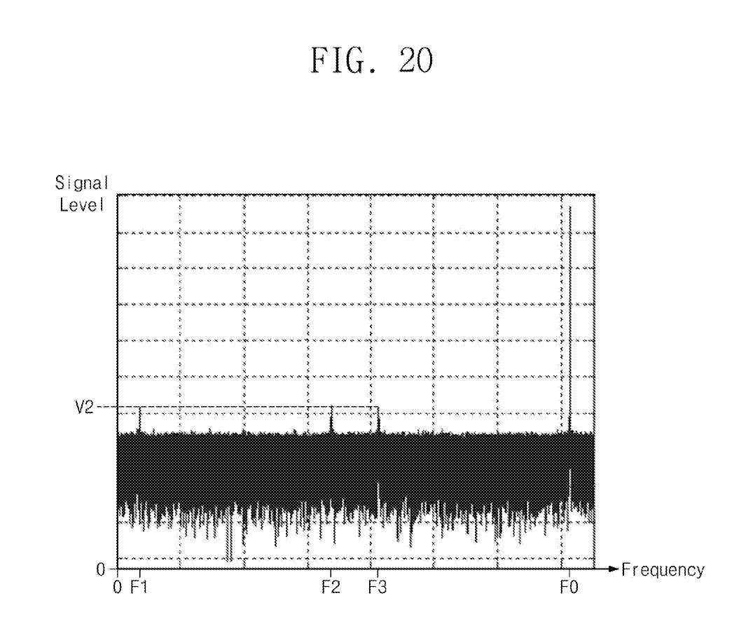

FIGS. 17 and 18 are graphs illustrating results of example simulations in which the skew between conversion clocks CLK1, CLK2, CLK3, and CLK4 is adjusted according to some example embodiments.

FIG. 17 illustrates a result of a simulation performed when a frequency of the input signal is relatively high, and FIG. 18 illustrates a result of a simulation performed when the frequency of the input signal is relatively low. Referring to FIGS. 17 and 18, it may be understood that while the input signal continues to be received, a level of an error (i.e., a difference between an intended sample and an actual sample) gradually converges to zero.

The error level converging to zero may mean that a timing error between the conversion clocks CLK1, CLK2, CLK3, and CLK4 is resolved. Thus, it may be understood that example embodiments of the present disclosure may provide meaningful designs to resolve timing errors between a plurality of clocks, irrespective of the frequency of the input signal.

FIGS. 19 and 20 are graphs illustrating results of example simulations in which the skew between conversion clocks CLK1, CLK2, CLK3, and CLK4 is adjusted according to some example embodiments.

FIG. 19 illustrates signal levels of outputs obtained before the skew between the conversion clocks CLK1, CLK2, CLK3, and CLK4 is adjusted, and FIG. 20 illustrates the signal levels of the outputs obtained after the skew between the conversion clocks CLK1, CLK2, CLK3, and CLK4 is adjusted. Referring to FIGS. 19 and 20, a frequency F0 may correspond to a clock frequency that is intended to operate the ADC circuit 200. On the other hand, frequencies F1, F2 and F3 may be associated with outputs obtained due to a timing error between the conversion clocks CLK1, CLK2, CLK3 and CLK4.

Comparing FIG. 20 with FIG. 19, it may be understood that, as the skew between the conversion clocks CLK1, CLK2, CLK3, and CLK4 is adjusted, levels of signals having the frequencies F1, F2 and F3 resulting from the timing error decreases from a higher value V1 to a lower value V2. That is, it may be understood that example embodiments of the present disclosure are useful to adjust intervals between a plurality of clocks to be uniform.

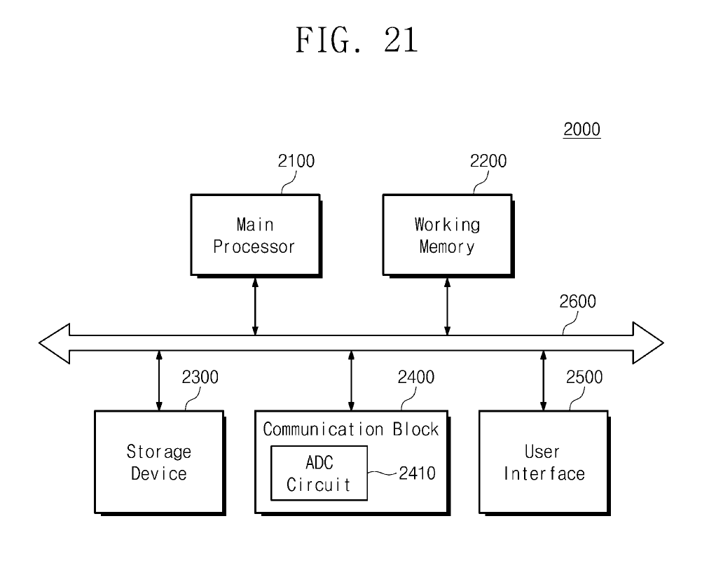

FIG. 21 is a block diagram illustrating an example configuration of an electronic system 2000 which employs an ADC circuit according to some example embodiments.

The electronic system 2000 may include a main processor 2100, a working memory 2200, a storage device 2300, a communication block 2400, a user interface 2500, and a bus 2600. For example, the electronic device 2000 may be one of electronic devices such as a desktop computer, a laptop computer, a tablet computer, a smart phone, a wearable device, an electric vehicle, a workstation, a server, and/or the like.

The main processor 2100 may control the overall operations of the electronic system 2000. The main processor 2100 may process various kinds of arithmetic and/or logical operations. For example, the main processor 2100 may be implemented with a general purpose processor, a dedicated processor, or an application processor.

The working memory 2200 may store data used in the operation of the electronic system 2000. For example, the working memory 2200 may temporarily store data processed or to be processed by the main processor 2100. For example, the working memory 2200 may include a volatile memory such as a dynamic random access memory (DRAM), a synchronous DRAM (SDRAM), and the like, and/or a nonvolatile memory such as a phase-change RAM (PRAM), a magneto-resistive RAM (MRAM), a resistive RAM (ReRAM), a ferro-electric RAM (FRAM), and the like.

A memory device of the storage device 2300 may store data regardless of power supply. For example, the storage device 2300 may include a nonvolatile memory such as a flash memory, a PRAM, an MRAM, a ReRAM, an FRAM, and the like. For example, the storage device 2300 may include storage media such as a hard disk drive (HDD), a solid state drive (SSD), a card storage, an embedded storage, and/or the like.

The communication block 2400 may communicate with an external device/system of the electronic system 2000. The communication block 2400 may be a component capable of providing communication services, such as a modulator/demodulator (MODEM) chip or device, a network card, a communication switch, a hub, a router, and/or the like. For example, the communication block 2400 may support at least one of a variety of wireless communication protocols such as LTE, WIMAX, GSM, CDMA, Bluetooth, near field communication (NFC), Wi-Fi, RFID, and the like, and/or at least one of various wired communication protocols such as TCP/IP, USB, Firewire, and the like.

The communication block 2400 may include various electronic circuits such as a transmission circuit, a reception circuit, an ADC circuit 2410, and/or the like, to provide communication services. The ADC circuit 2410 may adjust timings of a plurality of clocks according to example embodiments of the present disclosure, and may resolve a timing error between the plurality of clocks. To this end, the ADC circuit 2410 may be implemented according to the example embodiments described with reference to FIGS. 1 to 16 and various other example embodiments modified from the example embodiments.

The user interface 2500 may arbitrate in communication between a user and the electronic system 2000. For example, the user interface 2500 may include an input interface such as a keyboard, a mouse, a keypad, a button, a touch panel, a touch screen, a touch pad, a touch ball, a camera, a microphone, a gyroscope sensor, a vibration sensor, and/or the like. For example, the user interface 2500 may include an output interface such as a liquid crystal display (LCD) device, a light emitting diode (LED) display device, an organic LED (OLED) display device, an active matrix OLED (AMOLED) display device, a speaker, a motor, and/or the like.

The bus 2600 may provide a communication path between components of the electronic system 2000. The components of the electronic system 2000 may exchange data with each other based on a bus format of the bus 2600. For example, the bus format may include at least one of various interface protocols such as USB, small computer system interface (SCSI), peripheral component interconnect express (PCIe), mobile PCIe (M-PCIe), advanced technology attachment(ATA), parallel ATA (PATA), serial ATA (SATA), serial attached SCSI (SAS), integrated drive electronics (IDE), enhanced IDE (EIDE), nonvolatile memory express (NVMe), universal flash storage (UFS), and/or the like.

Meanwhile, the above descriptions have been provided to describe an ADC circuit employed with regard to communications, but the present disclosure is not limited to the above descriptions. The ADC circuit according to example embodiments of the present disclosure may be employed in any type of electronic device/circuit. Further, example embodiments of the present disclosure may be employed in another type of electronic circuit other than an ADC circuit. Example embodiments of the present disclosure may be employed in any type of electronic circuit operating based on a plurality of clocks which is time-interleaved.

The configuration illustrated in each block diagram is provided to facilitate better understanding. Each block may be implemented in smaller units of blocks depending on its function. Alternatively, a plurality of blocks may be implemented in a larger unit of block depending on their functions. The present disclosure is not limited to the configuration illustrated in each block diagram.

In the above, the present disclosure has been described based on some example embodiments. However, due to the nature of the technical field to which the present disclosure belongs, the purpose and the effect of the present disclosure may be achieved by other implementations which are different from the above example embodiments but include the subject matters of the present disclosure. Accordingly, the above example embodiments should be understood in a descriptive sense, not in a limited perspective sense. That is, implementations, that may achieve the same purpose and the effect as those of the above example embodiments while including the subject matters of the present disclosure, should be construed as being covered by the scope of protection claimed below.

Accordingly, implementations that are altered or modified without departing from characteristics of the present disclosure will fall within the scope of protection claimed below. Also, it should be understood that the scope of protection of the present disclosure is not limited to the above example embodiments, but covers the technical concepts which is read from the following claims.

What is claimed is:

1. An electronic circuit comprising:
a reference analog-to-digital converter (ADC) to convert an input signal to reference data, in response to a reference clock;
a plurality of delay circuits to delay a main clock by different delay times, to output a plurality of conversion clocks which provide different timings;
a plurality of sub-ADCs to convert the input signal to a plurality of output data, in response to the plurality of conversion clocks;
a subtractor to calculate a difference between the reference data and each of the plurality of output data; and
an edge detector to generate delay calibration values, based on the difference and output data corresponding to the difference among the plurality of output data, wherein
to adjust a timing of a conversion clock associated with a sub-ADC which outputs the corresponding output data among the plurality of sub-ADCs, a delay time of a delay circuit which outputs the associated conversion clock among the plurality of delay circuits is adjusted based on the delay calibration values.

2. The electronic circuit of claim 1, wherein
the plurality of conversion clocks is time-interleaved such that the input signal is sampled successively at each of the different timings.

3. The electronic circuit of claim 1, wherein
a period of the reference clock is longer than a period of each of the plurality of conversion clocks, and
a timing of the reference clock corresponds to a timing of a different conversion clock for each period of the reference clock.

4. The electronic circuit of claim 1, wherein
output data used to calculate the difference among the plurality of output data is changed among the plurality of output data whenever the subtractor calculates the difference.

5. The electronic circuit of claim 1, wherein
when the delay time of the delay circuit which outputs the associated conversion clock increases based on the delay calibration values, the timing of the associated conversion clock is delayed, and
when the delay time of the delay circuit which outputs the associated conversion clock decreases based on the delay calibration values, the timing of the associated conversion clock is advanced.

6. The electronic circuit of claim 1, wherein
the subtractor is to perform a subtraction operation on all of a plurality of bits of each of the reference data and the plurality of output data, to calculate the difference.

7. The electronic circuit of claim 1, wherein
the edge detector is to generate the delay calibration values based on a most significant bit (MSB) of the output data corresponding to the difference.

8. The electronic circuit of claim 1, further comprising an accumulator to accumulate the delay calibration values output from the edge detector, to generate a final correction value, wherein
the delay time of the delay circuit which outputs the associated conversion clock increases or decreases based on the final correction value.

9. The electronic circuit of claim 8, wherein
the accumulator is to accumulate the delay calibration values output from the edge detector, for a reference time duration or until a reference number of delay calibration values is accumulated.

10. An electronic circuit comprising:
a reference analog-to-digital converter (ADC) to convert an input signal to reference data, in response to a reference clock; and
a plurality of sub-ADCs to respectively convert the input signal to a plurality of output data in response respectively to a plurality of conversion clocks providing different timings, wherein
based on a difference between the reference data and each of the plurality of output data and output data corresponding to the difference among the plurality of output data, a timing of a conversion clock associated with the corresponding output data among the plurality of conversion clocks is adjusted.

11. The electronic circuit of claim 10, further comprising an edge detector to combine a change in a value of the difference with a value of the corresponding output data, to generate a delay calibration value, wherein
the timing of the associated conversion clock is adjusted based on the delay calibration value.

12. The electronic circuit of claim 11, wherein
when the value of the difference is changed from a first logic value to a second logic value while the corresponding output data corresponds to the first logic value, the timing of the associated conversion clock is delayed based on the delay calibration value.

13. The electronic circuit of claim 11, wherein
when the value of the difference is changed from a second logic value to a first logic value while the corresponding output data corresponds to the first logic value, the timing of the associated conversion clock is advanced based on the delay calibration value.

14. The electronic circuit of claim 10, wherein
differences between the reference data and all the plurality of output data are calculated, and
the different timings of the plurality of conversion clocks respectively associated with the plurality of output data are adjusted based respectively on the differences.

15. The electronic circuit of claim 14, wherein
as the different timings of the plurality of conversion clocks are adjusted, intervals between the different timings of the plurality of conversion clocks become uniform.

16. An electronic circuit comprising:
a plurality of delay circuits to output a plurality of clocks providing different timings according to different delay times;
a subtractor to calculate a difference between reference data and each of a plurality of output data, the plurality of output data being generated in response to the plurality of clocks; and
an edge detector to, when a value of the difference is changed while a value of output data corresponding to the difference among the plurality of output data is maintained, generate delay calibration values based on the corresponding output data and a change in the value of the difference, to adjust a timing of a clock associated with the corresponding output data among the plurality of clocks.

17. The electronic circuit of claim 16, wherein
a delay time of a delay circuit which outputs the associated clock among the plurality of delay circuits is adjusted based on the delay calibration values.

18. The electronic circuit of claim 16, wherein
when the value of the difference is changed from a first logic value to a second logic value while the value of the corresponding output data is maintained at the first logic value, a delay time of a delay circuit which outputs the associated clock among the plurality of delay circuits increases based on the delay calibration values.

19. The electronic circuit of claim 16, wherein
when the value of the difference is changed from a second logic value to a first logic value while the value of the corresponding output data is maintained at the first logic value, a delay time of a delay circuit which outputs the associated clock among the plurality of delay circuits decreases based on the delay calibration values.

20. The electronic circuit of claim 16, wherein
the different delay times of the plurality of delay circuits are independently adjusted based on the delay calibration values.
